(19) United States
(12) Patent Application Publication
(10) Pub. No.: US 2011/0068401 A1
(43) Pub. Date: Mar. 24, 2011

(54) SEMICONDUCTOR DEVICE AND METHOD OF MANUFACTURING THE SAME

(75) Inventors: Takashi Izumida, Kanagawa (JP); Nobutoshi Aoki, Kanagawa (JP); Masaki Kondo, Kanagawa (JP); Yoshiaki Asao, Kanagawa (JP); Satoshi Inaba, Kanagawa (JP)

(73) Assignee: KABUSHIKI KAISHA TOSHIBA, Tokyo (JP)

(21) Appl. No.: 12/881,415

(22) Filed: Sep. 14, 2010

(30) Foreign Application Priority Data
Sep. 24, 2009 (JP) 2009-219660

(51) Int. Cl. H01L 27/12; H01L 21/84

(52) U.S. Cl. 257/347; 438/151; 257/E27.111; 257/E21.703

(57) ABSTRACT

A semiconductor device of an embodiment includes a substrate and a plurality of fins formed on the substrate. The plurality of fins is arranged so that a first distance and a second distance narrower than the first distance are repeated. In addition, the plurality of fins include a semiconductor region in which an impurity concentration of lower portions of side surfaces facing each other in sides forming the first distance is higher than an impurity concentration of lower portions of side surfaces facing each other in sides forming the second distance.

### CROSS-REFERENCE TO RELATED APPLICATIONS

This application is based upon and claims the benefit of priority from prior Japanese Patent Application No. 2009-219660, filed on Sep. 24, 2009, the entire contents of which are incorporated herein by reference.

### FIELD

Embodiments described herein relate generally to a semiconductor device and method of manufacturing the same.

### BACKGROUND

As a conventional transistor, a double gate Fin-Field Effect Transistor (FinFET) that includes a plurality of fins aligned equidistantly is known.

The double gate FinFET includes a gate electrode formed perpendicular to a longitudinal direction of the fins so as to sandwich the fins, and a single crystal Si grown epitaxially in an upper surface and a side surface of the fins located at both sides of the gate electrode connects the fins adjacent to each other. The fins adjacent to each other are connected to each other, so that contacts can be easily formed on the fins, and parasitic resistance between source/drain regions can be reduced.

However, the conventional double gate FinFET has a plurality of fins aligned at narrow distances, so that when an impurity is introduced into the fins, there is a problem that the impurity is not sufficiently introduced into a lower portion of the fins.

### BRIEF DESCRIPTION OF THE DRAWINGS

FIG. 1 is a perspective view schematically showing the primary portion of a FinFET of a semiconductor device according to a first embodiment;

FIG. 2 is a top view schematically showing the primary portion of the FinFET of the semiconductor device according to the first embodiment;

FIGS. 3A to 3M are cross-sectional views taken along the line III-III in FIG. 2 showing manufacturing steps of the FinFET of the semiconductor device according to the first embodiment;

FIGS. 4A to 4M are cross-sectional views taken along the line IV-IV in FIG. 2 showing manufacturing steps of the FinFET of the semiconductor device according to the first embodiment; FIGS. 5A to 5M are cross-sectional views taken along the line V-V in FIG. 2 showing manufacturing steps of the FinFET of the semiconductor device according to the first embodiment;

FIG. 6 is an explanatory view schematically showing a distribution of impurity in the fins and an element separation part of the FinFET of the semiconductor device according to the first embodiment;

FIG. 7 is a top view schematically showing the primary portion of the FinFET of the semiconductor device according to a second embodiment;

FIG. 8 is a cross-sectional view taken along the line VIII-VIII in FIG. 7 showing the FinFET of the semiconductor device according to the second embodiment;

FIG. 9 is a top view schematically showing the primary portion of the FinFET of the semiconductor device according to a third embodiment;

FIGS. 10A to 10L are cross-sectional views taken along the line X-X in FIG. 9 showing manufacturing steps of the FinFET of the semiconductor device according to the third embodiment;

FIG. 11 is a top view schematically showing the primary portion of the FinFET of the semiconductor device according to the fourth embodiment;

FIG. 12 is a cross-sectional view taken along the line XII-XII in FIG. 11 showing the FinFET of the semiconductor device according to the fourth embodiment;

FIG. 13 is a top view schematically showing the primary portion of the FinFET of the semiconductor device according to the fifth embodiment;

FIG. 14 is an explanatory view schematically showing a SRAM using the FinFET of the semiconductor device according to a sixth embodiment; and

FIGS. 15A and 15B are cross-sectional views schematically showing the primary portion of modifications of the FinFET of the semiconductor device according to the embodiments.

### DETAILED DESCRIPTION

A semiconductor device of an embodiment includes a substrate and a plurality of fins formed on the substrate. The plurality of fins is arranged so that a first distance and a second distance narrower than the first distance are repeated. In addition, the plurality of fins include a semiconductor region in which an impurity concentration of lower portions of side surfaces facing each other in sides forming the first distance is higher than an impurity concentration of lower portions of side surfaces facing each other in sides forming the second distance.

### First Embodiment

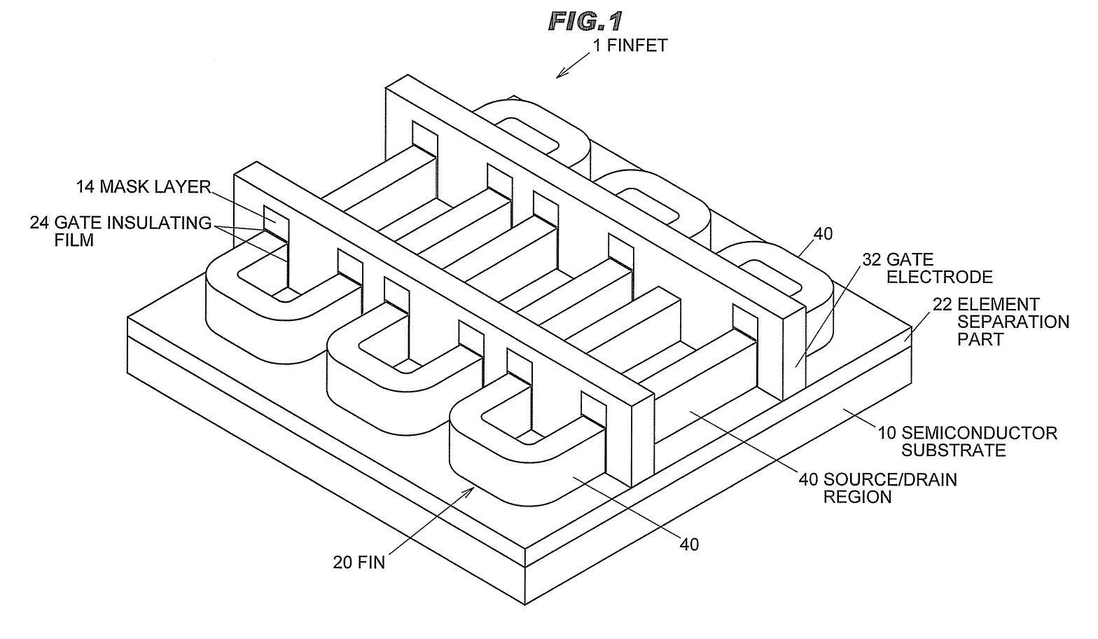

FIG. 1 is a perspective view schematically showing the primary portion of a FinFET of a semiconductor device according to a first embodiment.

The FinFET 1 is a double gate transistor formed of a plurality of fins. As shown in FIG. 1, the FinFET 1 is roughly configured to include a semiconductor substrate 10 as a substrate, a plurality of fins 20 formed of the semiconductor substrate 10, an element separation part 22 formed on the semiconductor substrate 10, source/drain regions 40 formed in the fins 20 and two gate electrodes 32 formed perpendicular to an extension direction of the fins 20.

As the semiconductor substrate 10, for example, a p-type Si based substrate including Si as a main component is used.

The element separation part 22 is formed on the semiconductor substrate 10 so as to electrically insulate the FinFET 1 from the other elements, and is formed of, for example, an insulating material such as a SiN, a SiO₂, a tetraethyl orthosilicate (TEOS).

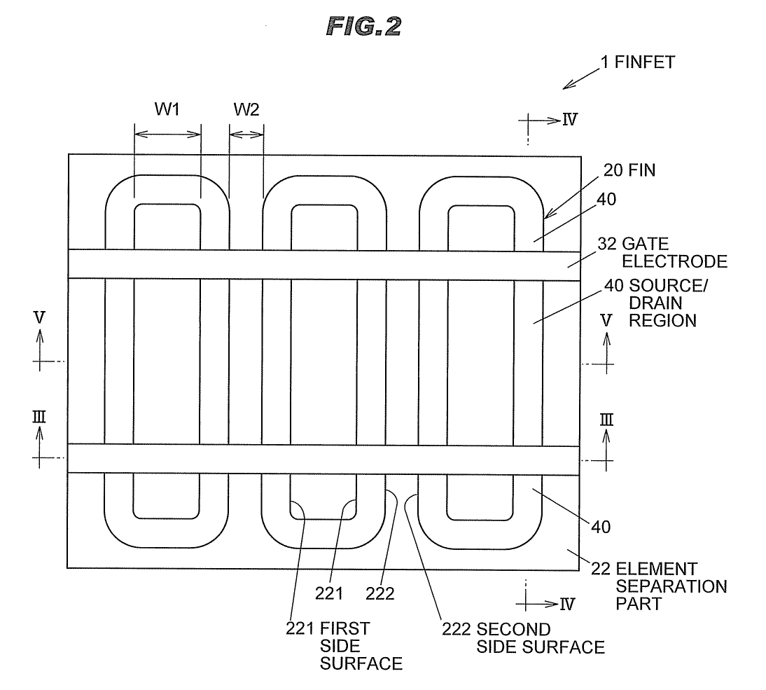

FIG. 2 is a top view schematically showing the primary portion of the FinFET of the semiconductor device according to the first embodiment. As shown in FIG. 2, the fins 20 form a closed loop by that end portions of two fins 20 adjacent to each other are connected. A distance (W1) as a first distance between the fins 20 in the closed loop is, for example, 50 nm, and a distance (W2) as a second distance between the closed loops is, for example, 20 nm. The fins 20 form the closed loop by two fins 20 having a wide distance. The fins 20 have a width of, for example, 20 nm.

Hereinafter, a method of manufacturing the FinFET 1 according to the embodiment will be explained.

### (Method of Manufacturing Semiconductor Device)

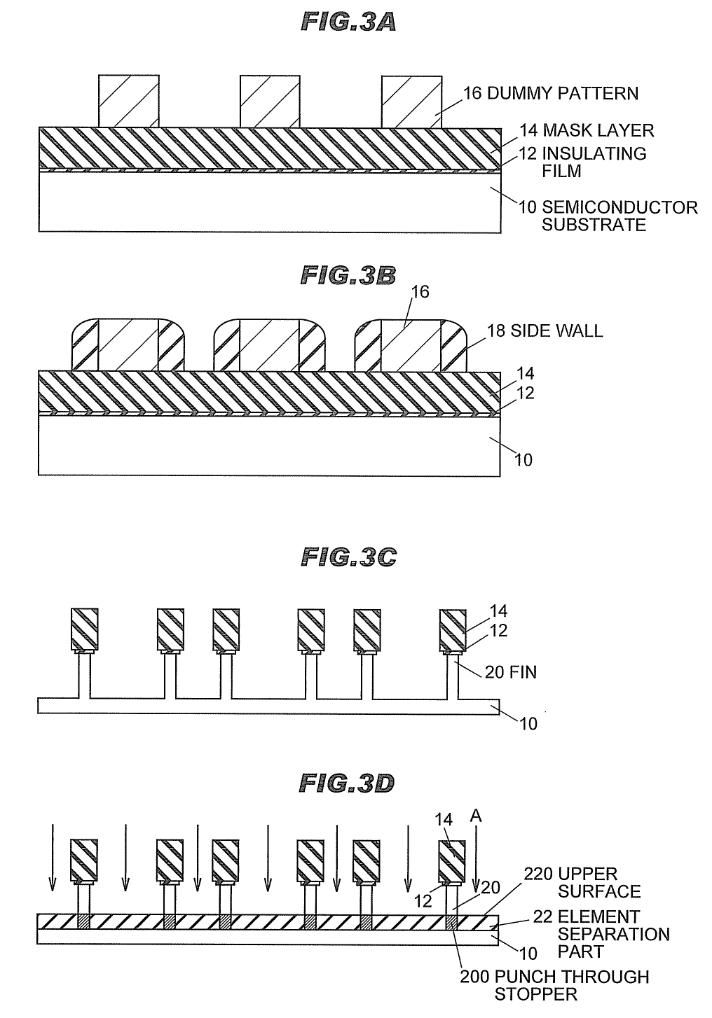

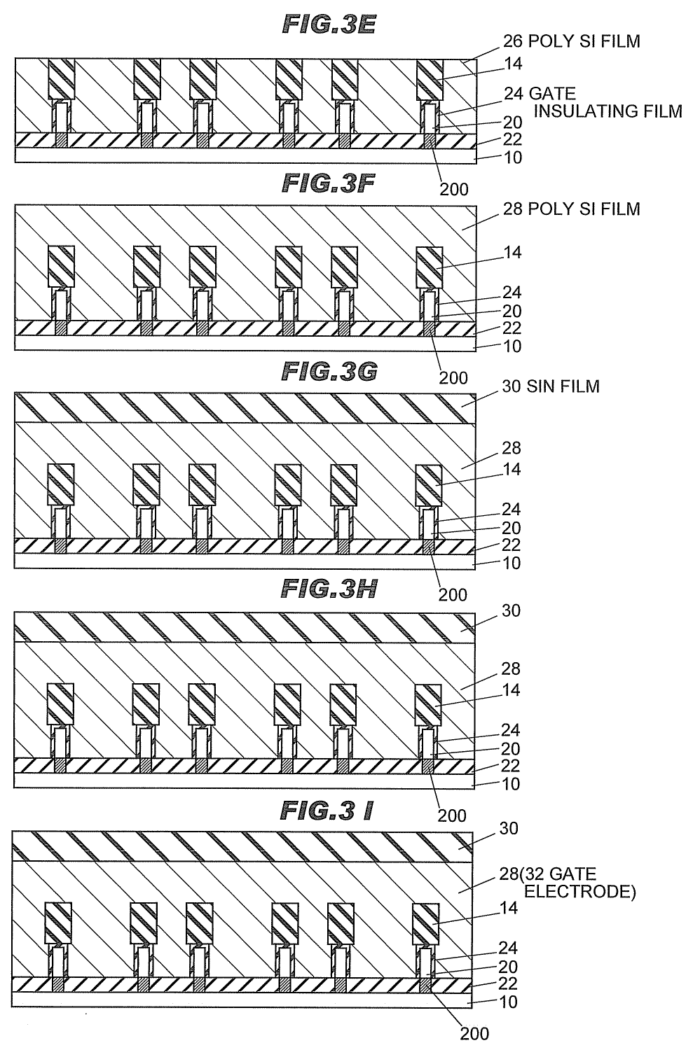

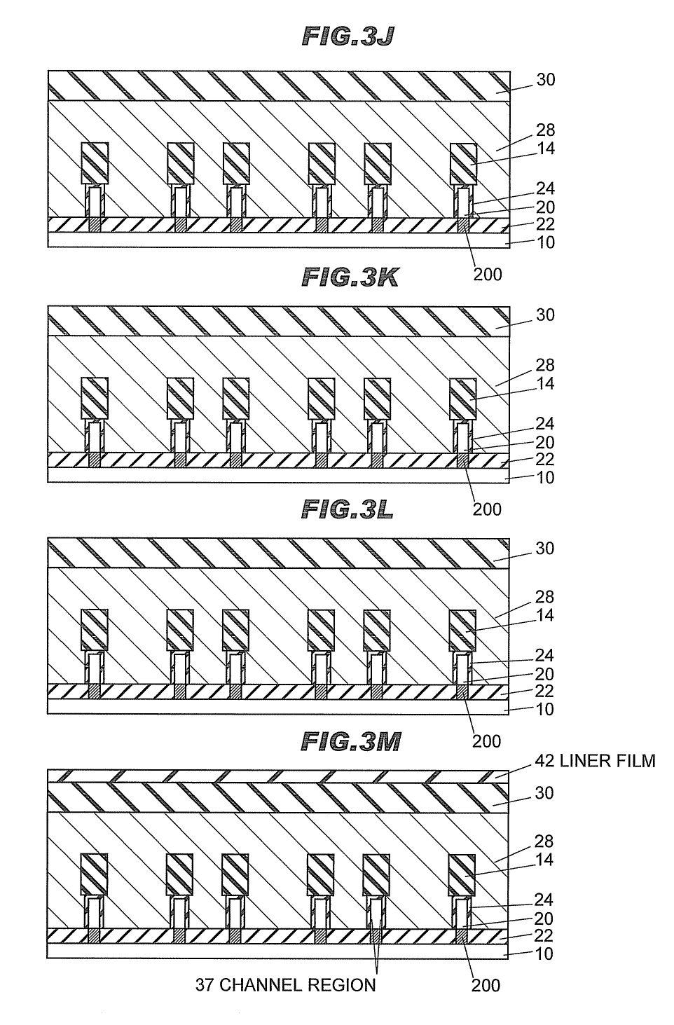

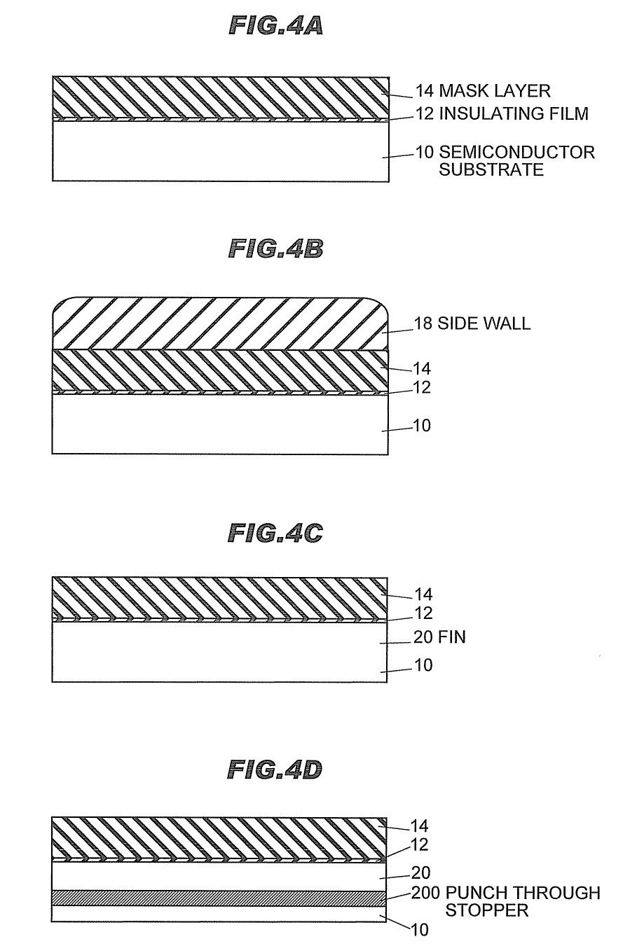

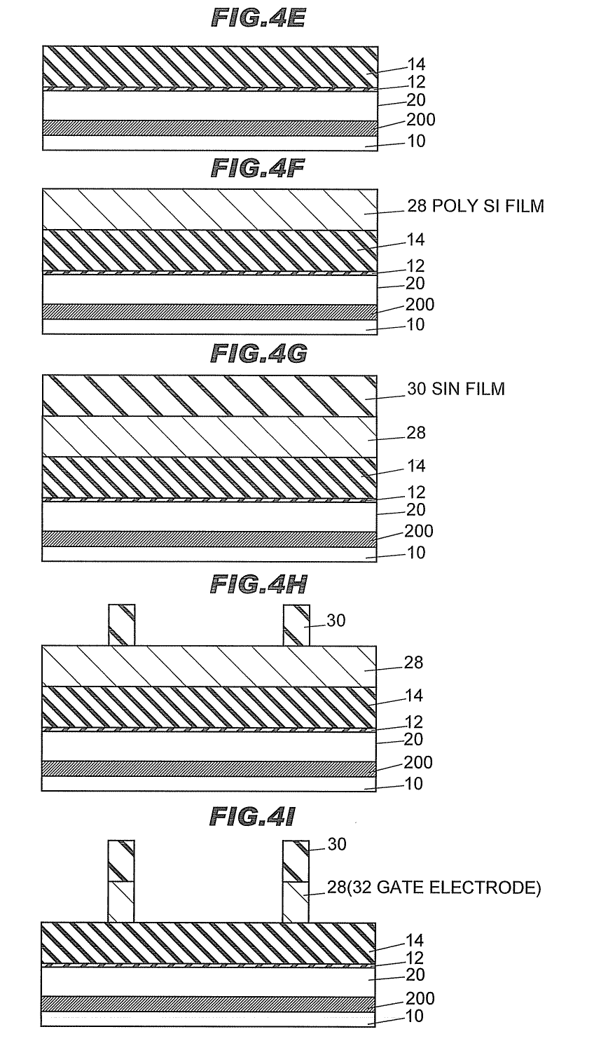

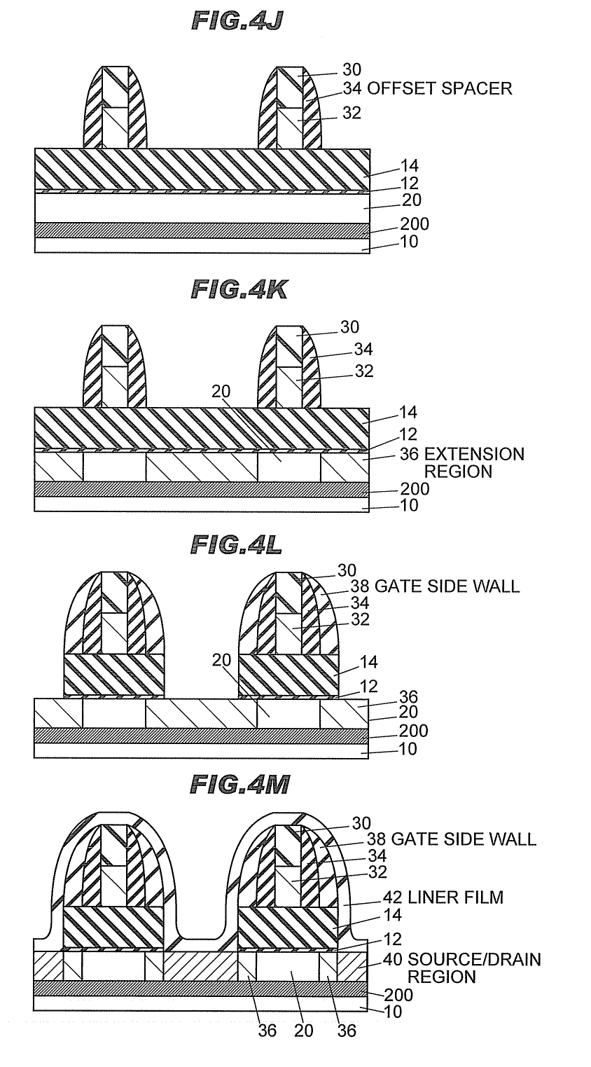

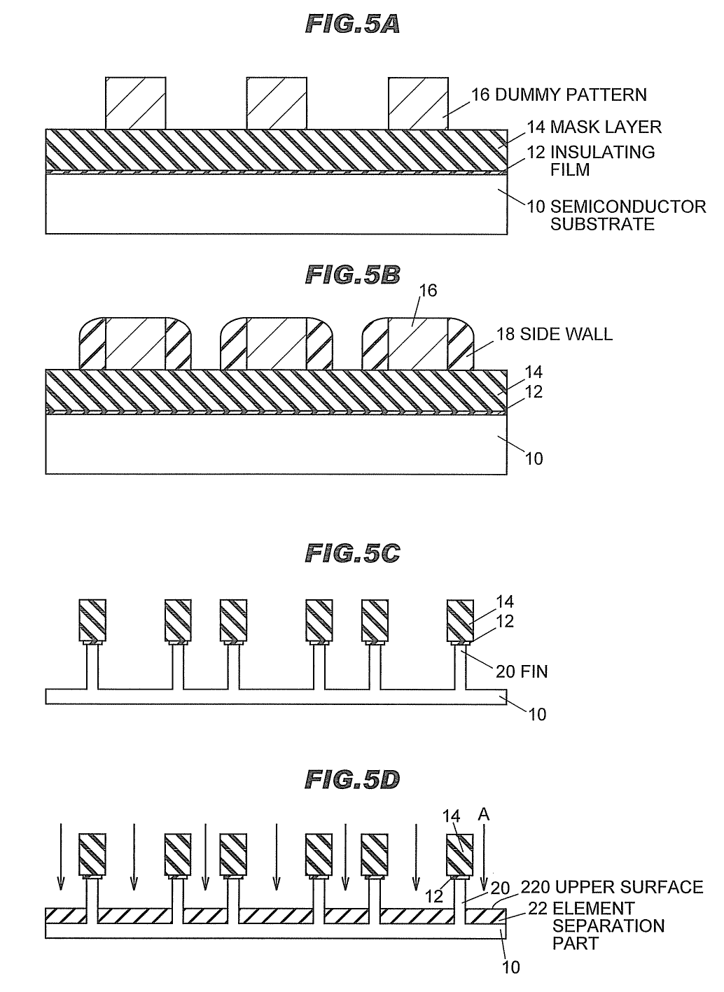

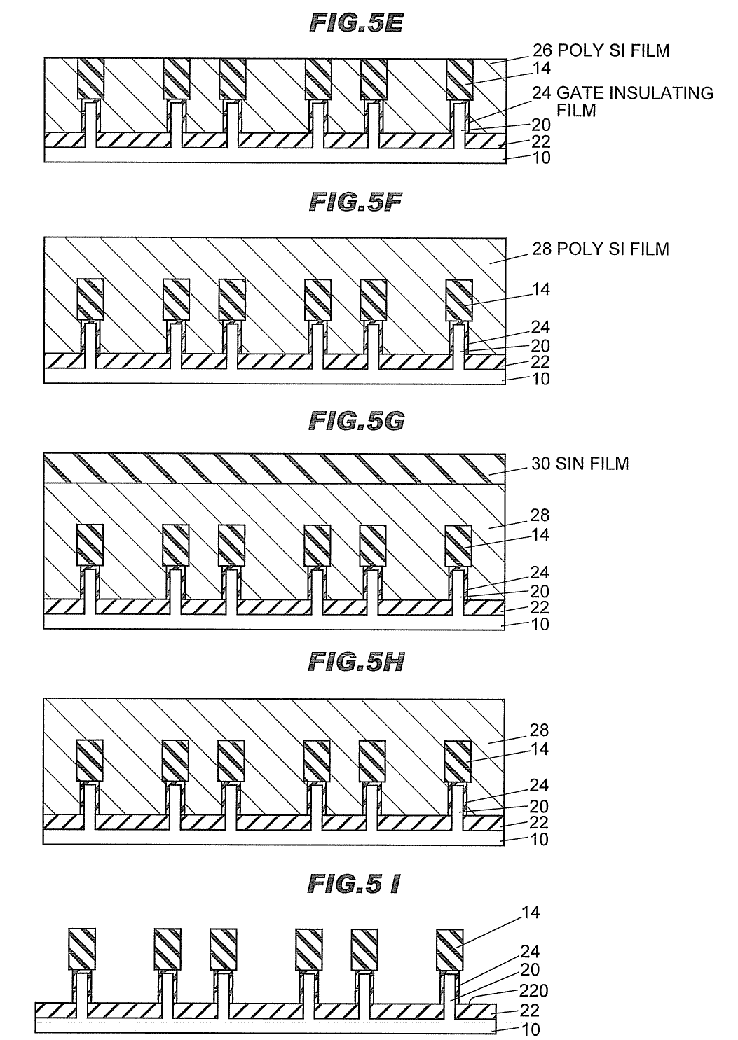

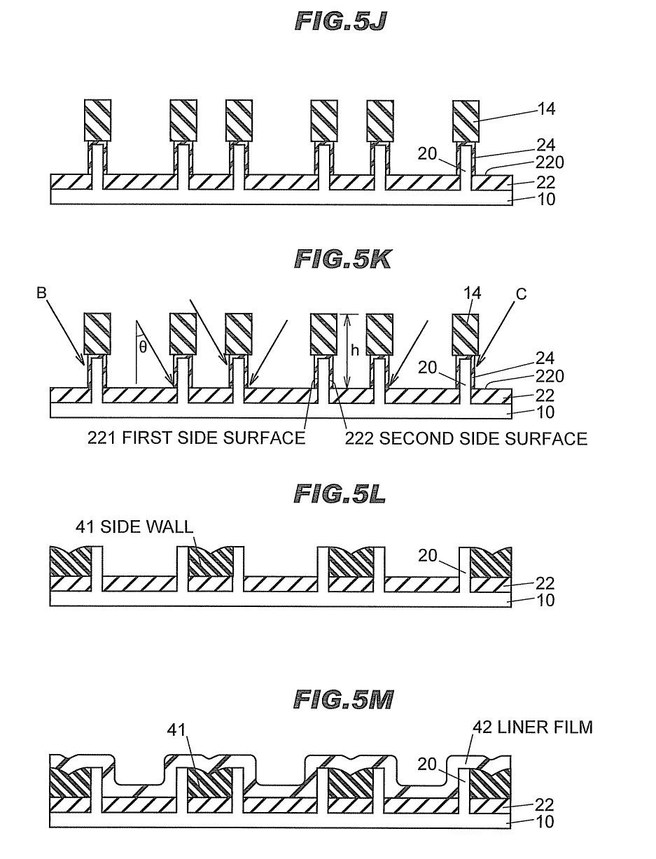

FIGS. 3A to 3M are cross-sectional views taken along the line in FIG. 2 showing manufacturing steps of the FinFET of the semiconductor device according to the first embodiment. FIGS. 4A to 4M are cross-sectional views taken along the line IV-IV in FIG. 2 showing manufacturing steps of the FinFET of the semiconductor device according to the first embodiment. FIGS. 5A to 5M are cross-sectional views taken along the line V-V in FIG. 2 showing manufacturing steps of the FinFET of the semiconductor device according to the first embodiment.

First, an insulating film 12 formed of, for example, a SiO₂ is formed on the semiconductor substrate 10 by a thermal oxidation method, a chemical vapor deposition (CVD) method or the like. Subsequently, a mask layer 14 formed of, for example, a SiN is formed on the formed insulating film 12 by the CVD method or the like. Further, the mask layer 14 can be formed of a stacked film instead of a single film. The mask layer 14 can be formed by, for example, stacking the SiN layer and the SiO₂ layer sequentially on the semiconductor substrate 10.

Next, as shown in FIGS. 3A, 4A and 5A, a dummy pattern 16 formed of a resist material is formed on the mask layer 14 by a photolithography method or the like.

The dummy pattern 16 is a pattern that is used as core materials of side walls to be used as a mask for forming the fins 20 to form the closed loop. The dummy pattern 16 has a line width (for example, 50 nm) equal to the distance (W1) between the fins 20 constituting one closed loop. A distance between the dummy patterns 16 is, for example, 60 nm, and a plurality of dummy patterns 16 are aligned on the mask layer 14 at the above-mentioned distances.

Next, as shown in FIGS. 3B, 4B and 5B, side walls 18 are formed on side surfaces of the dummy patterns 16 by that a SiO₂ film, for example, having a film thickness of 20 nm that is equal to the width of the fins 20 to be formed is formed by the CVD method or the like so as to cover the dummy pattern 16 and the mask layer 14 under the dummy pattern 16, and an etch-back is carried out by the film thickness by a reactive ion etching (RIE) method or the like.

Next, the dummy pattern 16 is removed, the mask layer 14 and the insulating film 12 are etched by the RIE method or the like in which the side walls 18 are used as a mask, and the side walls 18 are removed.

Next, as shown in FIGS. 3C, 4C and 5C, a part of the semiconductor substrate 10 is etched up to a desired depth by the RIE method or the like in which the remaining mask layer 14 is used as a mask. In this way, the plurality of fins 20 are formed.

Next, an insulating film (for example, SiO₂) is deposited by the CVD method or the like so as to cover the semiconductor substrate 10, the fin 20, the insulating film 12 and the mask layer 14. Subsequently, the insulating film deposited is planarized by a chemical mechanical polishing (CMP) method in which an upper surface of the mask layer 14 is used as a stopper, the insulating film is etched up to a predetermined depth by the RIE method or the like, and the element separation part 22 is formed on the semiconductor substrate 10. The predetermined depth is such that an upper surface 220 of the element separation part 22 becomes lower than an upper surface of the fines 20.

Next, as shown in FIGS. 3D, 4D and 5D, a p-type impurity (for example, B) is introduced into the element separation part 22 between the respective fins 20 by an ion implantation method from an A direction shown in the drawings that corresponds to a direction almost perpendicular to the upper surface 220. Subsequently, a heat treatment is carried out for the purpose of recovery of crystal defects and electrical activation of the impurity implanted.

Since there is the mask layer 14 in a top portion of the fins 20, the ion implantation is not directly carried out to the fins 20. However, the impurity implanted scatters and diffuses laterally in the element separation part 22, and it also scatters and diffuses into the fins 20. As a result, a punch through stopper 200 as a region in which an impurity concentration in the fins 20 is heightened is formed in a lower portion of a region to become a channel region. It is preferable that the punch through stopper 200 is formed only in the lower portion of a region to become the channel region, but even if it is formed in places other than the lower portion, for example, in a lower portion of the source/drain region 40, an impurity concentration of the source/drain region 40 is sufficiently high in comparison with that of the punch through stopper 200, so that characteristics of the transistor are not affected.

Next, side surfaces of the fins 20 are oxidized by the thermal oxidization method, and gate insulating films 24 formed of SiO₂ are formed on the side surfaces of the fins 20. Here, hereinafter, the insulating film 12 under the mask layer 14 and the SiO₂ formed by oxidizing the side surfaces of the fins 20 are collectively referred to as the gate insulating film 24.

Here, the gate insulating film 24 can be formed of, for example, a high dielectric constant insulating film such as a SiON, a HfSiON based on the CVD method, the RIE method and the like.

Next, a poly Si film 26 is formed so as to cover the element separation part 22, the gate insulating film 24 and the mask layer 14 based on the CVD method, for example, by depositing a poly Si into which an n-type impurity is introduced.

Next, as shown in FIGS. 3E, 4E and 5E, the poly Si film 26 is planarized by the CMP method or the like in which a surface of the mask layer 14 is used as a stopper.

Next, as shown in FIGS. 3F, 4F and 5F, a poly Si film 28 is formed on the poly Si film 26 planarized, based on the CVD method or the like by depositing the poly Si again.

Next, as shown in FIGS. 3G, 4G and 5G, a SiN film 30 is formed on the poly Si film 28 based on the CVD method or the like.

Next, as shown in FIGS. 3H, 4H and 5H, a mask formed of a resist film based on the gate electrode is formed on the SiN film 30 based on the photolithography method or the like, and the SiN film 30 is etched by the RIE method in which the resist film is used as a mask.

Next, as shown in FIGS. 3I, 4I and 5I, the poly Si film 28 under the SiN film 30 is etched up to a surface of the element separation part 22 by the RIE method or the like in which the SiN film 30 is used as a mask. In this way, two gate electrodes 32 are formed so as to cross the plural fins 20.

Next, as shown in FIGS. 3J, 4J and 5J, an offset spacer 34 is formed in side surfaces of the gate electrode 32 by the CVD method and the RIE method. The offset spacer 34 is, for example, an insulating material such as a SiN, a SiO₂.

In particular, a material film (for example, a SiN film) is deposited on the semiconductor substrate 10 by the CVD method or the like. Subsequently, the material film is etched by the RIE method, and the offset spacer 34 is formed in the side surfaces of the gate electrode 32 and the SiN film 30. At this time, by adjusting the etching condition, the material film of the offset spacer 34 deposited on the side surfaces of the fins 20 is removed and simultaneously the offset spacer 34 is formed in the side surfaces of the gate electrode 32 and the SiN film 30.

Next, as shown in FIGS. 3K, 4K and 5K, an n-type impurity (for example, As) of low concentration is introduced into each of the fins 20 by the ion implantation method in which the offset spacer 34 is used as a mask, and an extension region 36 is formed in the fins 20.

Here, the ion implantation to the fin 20 for forming the extension region 36 will be explained.

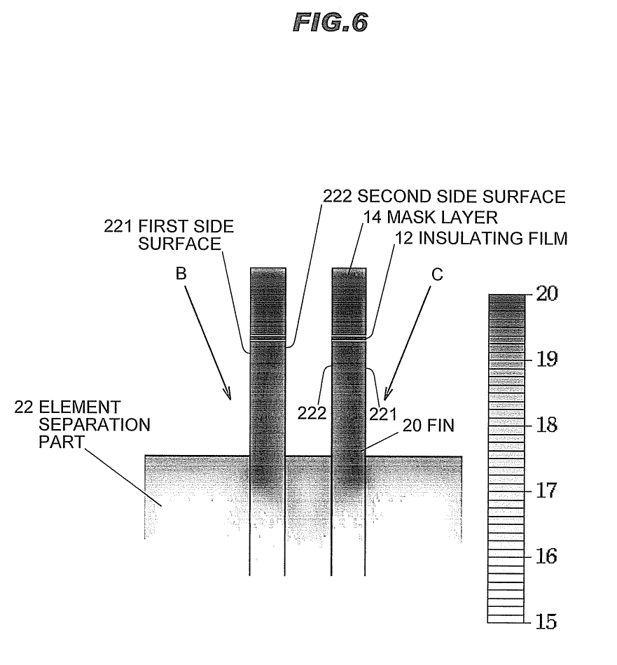

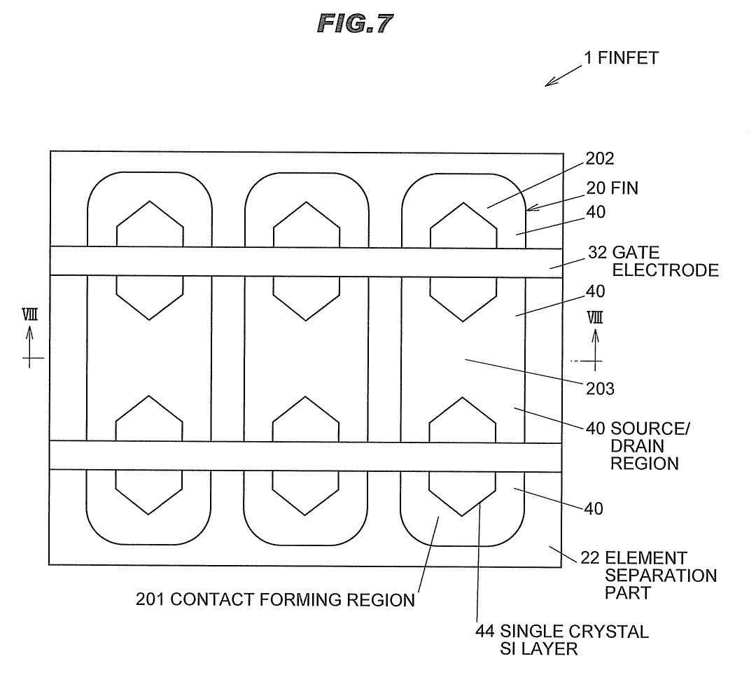

FIG. 6 is an explanatory view schematically showing a distribution of impurity in the fins and an element separation part of the FinFET of the semiconductor device according to the first embodiment. FIG. 6 shows a distribution of impurity based on a result of simulation in a range from 1×10¹⁵ to 1×10²⁰. The introduction of the n-type impurity is carried out under the condition that, for example, the n-type impurity is As, an acceleration voltage is 10 Key and a dose amount is 1×10¹⁴ cm⁻².

The ion implantation to each of the fins 20 is carried out, for example, as shown in FIG. 5K, first from a B direction, and subsequently from a C direction.

In addition, as shown in FIG. 5K, it becomes difficult to introduce the impurity up to lower sides of second side surfaces 222 of the fins 20 that face each other in a side aligned at narrow distances, in accordance with an increase in an integration degree of the FinFET 1.

In the embodiment, as shown in FIG. 6, the impurity is evenly introduced from an upper portion to a lower portion of a first side surface 221 that is a side surface of the fins 20 in a side aligned at wide distances, via the gate insulating film 24. Due to this, even if the impurity is not sufficiently introduced to a lower portion of the second side surface 222 that is a side surface of the fins 20 in a side aligned at narrow distances, the impurity is sufficiently introduced from the upper portion to the lower portion of the first side surface 221. In other words, the fins 20 include a semiconductor region in which an impurity concentration of the lower portions of the first side surfaces 221 of the wide distance is higher than an impurity concentration of the lower portions of the second side surfaces 222 of the narrow distance.

Further, an impurity implanting angle (θ) is calculated by using a height (h) from the upper surface 220 of the element separation part 22 to an upper portion surface of the mask layer 14, and the distance (W2) of narrow distance taking into account of a width of the gate insulating film 24 formed on the side surfaces of the fins 20.

Next, as shown in FIGS. 3L, 4L and 5L, a gate side wall 38 is formed on the side surface of the offset spacer 34 by the CVD method and the RIE method, the mask layer 14 and the gate insulating film 24 are removed by the RIE method in which the gate side wall 38 is used as a mask, and the upper surface and side surface of the fins 20 are exposed. After the etching for forming the gate side wall 38, a side wall 41 formed of an insulating material of the gate side wall 38 is formed on the second side surface 222 of the fins 20 aligned at narrow distance.

The gate side wall 38 is, for example, an insulating material such as a SiN, a SiO₂.

Next, as shown in FIGS. 3M, 4M and 5M, an n-type impurity (for example, As) of high concentration is introduced by the ion implantation method in which the gate side wall 38 is used as a mask, the source/drain region 40 is formed, subsequently a liner film 42 is formed by the CVD method, and the FinFET 1 is obtained via well-known steps. Here, as shown in FIG. 3M, the channel region 37 is formed adjacent to a border between the side surface of the fin 20 and the gate insulating film 24.

The introduction of the n-type impurity of high concentration is carried out at an angle similar to the angle of the ion implantation when the extension region 36 is formed, or at an angle based on the height from the surface of the element separation part 22 to the upper surface of the fins 20 and the distance (W2) of narrow distance. It is difficult to introduce the impurity from the upper portion to lower portion of second side surfaces 222 of the fins 20 that face each other in a side aligned at narrow distances, but from the first side surfaces 221 of the fins 20 that face each other in a side aligned at wide distances, the impurity is introduced from the upper portion to lower portion of the fins 20.

The liner film 42 is formed of, for example, a SIN.

### (Advantages of First Embodiment)

In accordance with the first embodiment, the following advantages can be obtained.
(1) The fins 20 are formed so as to have the wide distance (W1) and the narrow distance (W2) that are repeated, so that the impurity can be introduced easily into a lower portion of the fins 20 in comparison with a case that the fins are equidistantly formed.
(2) The fins 20 are formed so as to have the wide distance (W1) and the narrow distance (W2) that are repeated, consequently the impurity can be introduced into a lower portion of the fins 20, so that the parasitic resistance of the extension region 36 and the source/drain region 40 can be reduced in comparison with a case that the distance between the fins is narrow so that the impurity can not be sufficiently introduced from an upper portion to a lower portion of the fins.
(3) The fins 20 are formed so as to have the wide distance (W1) and the narrow distance (W2) that are repeated, consequently the impurity can be introduced into a lower portion of the fins 20, so that a FinFET excellent in the characteristics can be obtained in comparison with a case that the fins are equidistantly formed.

### Second Embodiment

A second embodiment is different from the first embodiment in that a single crystal Si is epitaxially grown in upper surfaces and side surfaces of the fins 20. In each of the embodiments described below, to the same elements in compositions and functions as those Of the first embodiment, the same references as used in the first embodiment will be used, and detail explanation will be omitted. In addition, a part of a manufacturing step that overlaps between the first embodiment will be explained simplistically.

FIG. 7 is a top view schematically showing the primary portion of the FinFET of the semiconductor device according to a second embodiment. As shown in FIG. 7, the FinFET 1 according to the embodiment is configured to have a composition that a single crystal Si is epitaxially grown in upper surfaces and side surfaces of the fins 20, until the fins 20 adjacent to each other so as to constitute the closed loop are mutually connected. Further, since the side walls 41 remain between the closed loops, it is prevented that the closed loops adjacent to each other are connected to each other due to the epitaxial growth of the single crystal Si.

The single crystal Si is epitaxially grown in upper surfaces and side surfaces of the fins 20, so that contact forming regions 201, 202 formed by that the fins 20 are connected to each other are formed in both end portions of the closed loop, and a contact forming region 203 is formed between the two gate electrodes 32. The contact forming regions 201, 202, 203 are such that contacts are formed in upper portions thereof.

Hereinafter, a method of manufacturing the FinFET 1 according to the embodiment will be explained.

### (Manufacturing of Semiconductor Device)

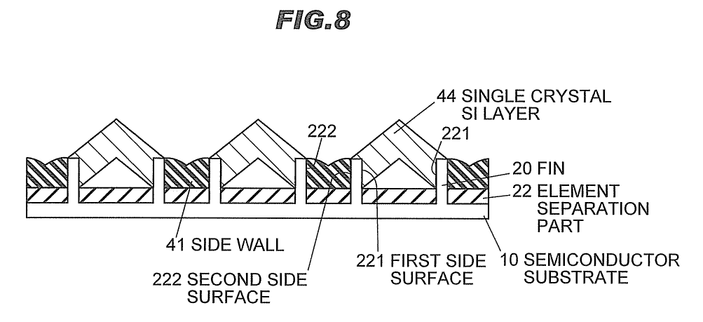

FIG. 8 is a cross-sectional view taken along the line VIII-VIII in FIG. 7 showing the FinFET of the semiconductor device according to the second embodiment.

The manufacturing steps of the semiconductor device according to the embodiment are carried out similarly to the manufacturing steps of the first embodiment shown in FIGS. 5A to 5K. Here, as shown in FIG. 8, when an insulating material deposited on the semiconductor substrate 10 is etched in the step of forming the gate side wall 38, the etching condition is adjusted so that the side wall 41 between the closed loops covers the second side surface 222 of the fins 20.

Next, as shown in FIG. 8, the single crystal Si is epitacially grown in the upper surfaces and the side surfaces of the fins 20 by the CVD method so as to form a single crystal Si layer 44 as a semiconductor layer, and the contact forming regions 201, 202, 203 are formed.

Next, the liner film 42 is formed by the CVD method, and via well-known steps, the FinFET 1 is obtained.

Further, the contacts are formed as follows. After the liner film 42 is formed, an interlayer insulating film formed of an insulating material is formed on the liner film 42 by the CVD method or the like, and holes corresponding to the contacts are formed in the interlayer insulating film on the contact forming regions 201, 202, 203 by the lithography method and the RIE method. Subsequently, the liner film 42 exposed in the holes is etched by the RIE method or the like, a conductive film formed of a conductive material is formed on the interlayer insulating film and in the holes by the deposition method or the like, and the conductive film on the interlayer insulating film is planarized by the CMP method or the like in which the interlayer insulating film is used as a stopper, so as to form the contacts.

### (Advantages of Second Embodiment)

In accordance with the second embodiment, when the single crystal Si layer 44 is epitaxially grown in an upper surface and a side surface of the fins 20, the side walls 41 are formed between the closed loops so that the single crystal Si is not grown, and the single crystal Si layer 44 is grown between the fins 20 constituting the closed loop and the fins 20 are connected to each other, so that the contacts to be connected to the contact forming regions 201 to 203 can be easily formed in an upper layer of the contact forming regions 201 to 203 that are parts connected, and a diffusing layer resistance and a contact resistance can be reduced.

### Third Embodiment

The third embodiment is different from the above-mentioned embodiments in that a distance (W3) between the fins 20 constituting the closed loop is narrower than a distance (W4) between the closed loops.

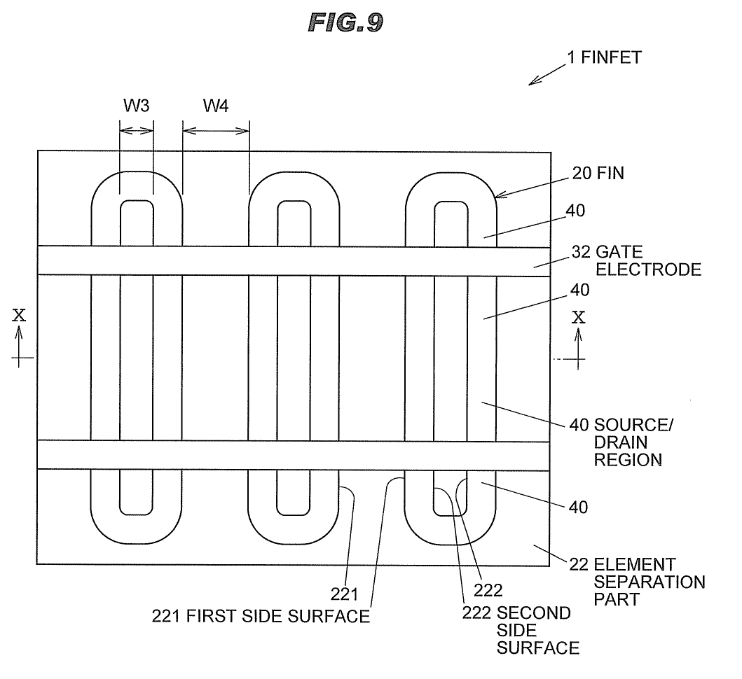

FIG. 9 is a top view schematically showing the primary portion of the FinFET of the semiconductor device according to a third embodiment. As shown in FIG. 9, the FinFET 1 is configured to have a composition that the distance (W3) between the fins 20 constituting the closed loop is narrower than the distance (W4) between the closed loops.

Hereinafter, a method of manufacturing the FinFET 1 will be explained.

### (Manufacturing of Semiconductor Device)

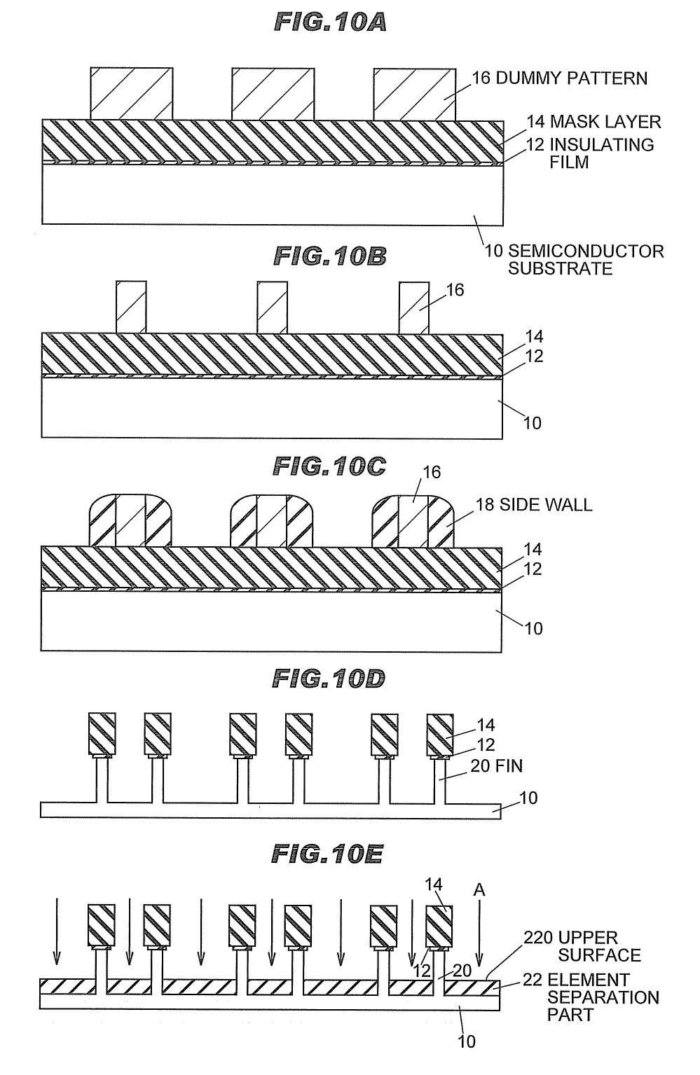

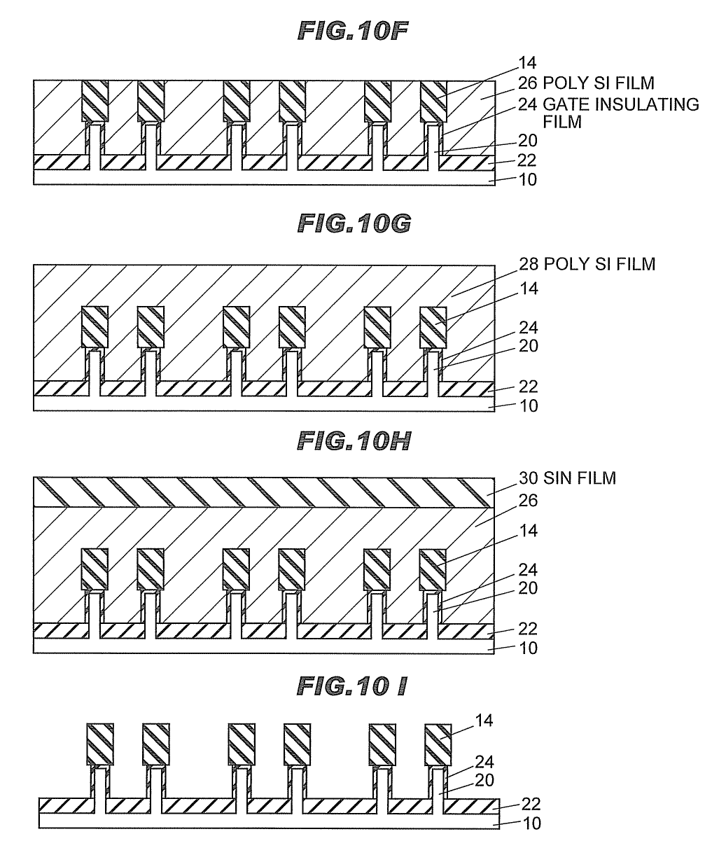

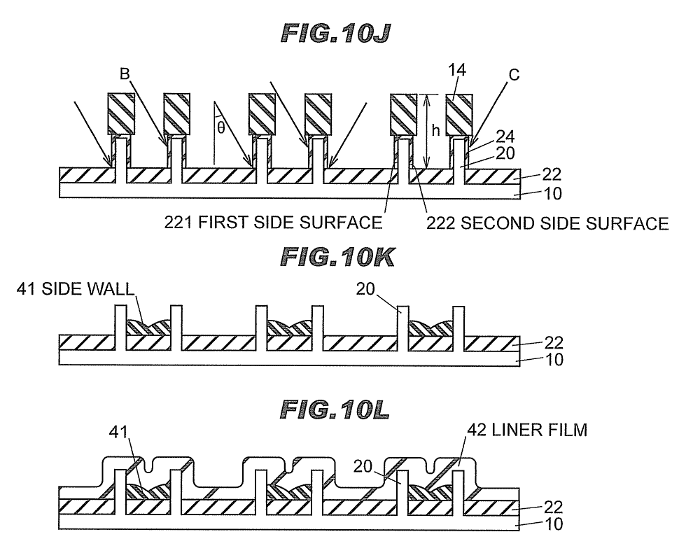

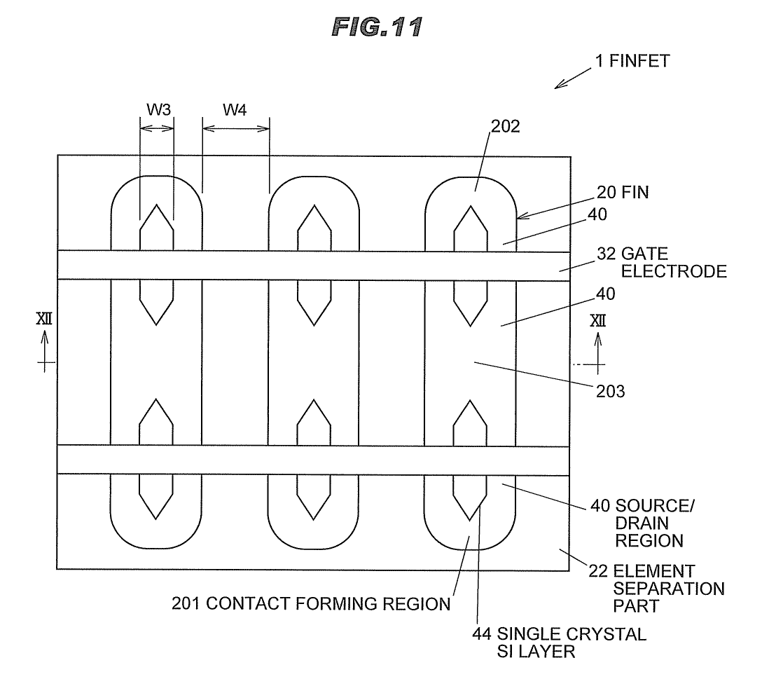

FIGS. 10A to 10L are cross-sectional views taken along the line X-X in FIG. 9 showing manufacturing steps of the FinFET of the semiconductor device according to the third embodiment. First, the insulating film 12 formed of, for example, a SiO₂ on the semiconductor substrate 10 by the thermal oxidation method, the CVD method or the like. Subsequently, the mask layer 14 formed of, for example, a SiN on the insulating film 12 formed by the CVD method or the like.

Next, as shown in FIG. 10A, the dummy patterns 16 formed of a resist material are formed on the mask layer 14 by the photolithography method or the like. The dummy patterns 16 are formed equidistantly.

Next, as shown in FIG. 10B, the dummy patterns 16 are slimmed in the width thereof so as to have a desired width (for example, 20 nm). As the slimming method, for example, a method that the slimming is carried out by a plasma etching using oxygen plasma, and a method that the slimming is carried out by that the surfaces of the dummy patterns 16 are allowed to be alkali soluble by an acidic chemical liquid, a development is carried out by a tetramethylammonium hydroxide (TMAH) aqueous solution, and subsequently a pure water rinse treatment is carried out, or the like is used.

Next, as shown in FIG. 10C, a SiO₂ is formed by the CVD method or the like so as to cover the dummy patterns 16 slimmed and the mask layer 14 under the dummy patterns 16, for example, in a film thickness (for example, 20 nm) equal to the width of the fin 20 to be formed, and an etch back is carried out by the film thickness by the RIE method or the like, so as to form the side walls 18 on the side surfaces of the dummy patterns 16.

Next, the dummy patterns 16 are removed, the mask layer 14 and the insulating film 12 are etched by the RIE method or the like in which the side walls 18 are used as a mask, and the side walls 18 are removed.

Next, as shown in FIG. 10D, a part of the semiconductor substrate 10 is etched up to a desired depth by the RIE method or the like in which the remaining mask layer 14 is used as a mask. In this way, plurality of the fins 20 is formed.

Next, an insulating film (for example, SiO₂) is deposited by the CVD method or the like so as to cover the semiconductor substrate 10, the fin 20, the insulating film 12 and the mask layer 14. Subsequently, the insulating film deposited is planarized up to the surface of the mask layer 14 by the CMP method, the insulating film is etched up to a predetermined depth by the RIE method or the like, and the element separation part 22 is formed on the semiconductor substrate 10. The predetermined depth is such that an upper surface 220 of the element separation part 22 becomes lower than an upper surface of the fines 20.

Next, as shown in FIG. 10E, a p-type impurity (for example, B) is introduced into the upper surface 220 of the element separation part 22 between the respective fins 20 by an ion implantation method from an A direction shown in the drawings that corresponds to a direction almost perpendicular to the upper surface 220. Subsequently, a heat treatment is carried out for the purpose of recovery of crystal defects and electrical activation of the impurity implanted.

Since there is the mask layer 14 in a top portion of the fins 20, the ion implantation is not directly carried out to the fins 20. However, the impurity implanted scatters and diffuses laterally from the upper surface 220 of the element separation part 22, and it also scatters and diffuses into the fins. As a result, a punch through stopper 200 as a region in which an impurity concentration in the fins 20 is heightened is formed in a lower portion of a region to become a channel region (refer to FIG. 3D).

Next, side surfaces of the fins 20 are oxidized by the thermal oxidization method, and gate insulating films 24 formed of SiO₂ are formed on the side surfaces of the fins 20.

Next, a poly Si film 26 is formed so as to cover the element separation part 22, the gate insulating film 24 and the mask layer 14 based on the CVD method, for example, by depositing a poly Si into which an n-type impurity is introduced.

Next, as shown in FIG. 10F, the poly Si film 26 is planarized by the CMP method or the like in which the mask layer 14 is used as a stopper.

Next, as shown in FIG. 10G, a poly Si film 28 is formed on the poly Si film 26 planarized, based on the CVD method or the like by depositing the poly Si again.

Next, as shown in FIG. 10H, a SiN film 30 is formed on the poly Si film 28 based on the CVD method or the like.

Next, a mask formed of a resist film based on the gate electrode is formed on the SiN film 30 based on the photolithography method or the like, and the SiN film 30 is etched by the RIE method in which the resist film is used as a mask.

Next, as shown in FIG. 10I, the poly Si film 28 under the

SiN film 30 is etched up to a surface of the element separation part 22 by the RIE method or the like in which the SiN film 30 is used as a mask. In this way, two gate electrodes 32 are formed so as to cross the plural fins 20 (refer to FIG. 4I).

Next, an offset spacer 34 is formed in the side surfaces of the gate electrode 32 by the CVD method and the RIE method (refer to FIG. 4J).

Next, as shown in FIG. 10J, an n-type impurity (for example, As) of low concentration is introduced into each of the fins 20 by the ion implantation method in which the offset spacer 34 is used as a mask, and an extension region 36 is formed in the fins 20 (refer to FIG. 4K).

The ion implantation to each of the fins 20 is carried out, for example, as shown in FIG. 10J, from an oblique direction of the B direction and the C direction.

In the embodiment, as shown in FIG. 6, the impurity is evenly introduced from an upper portion to a lower portion of a first side surface 221 that is a side surface of the fins 20 in a side aligned at wide distances, via the gate insulating film 24. Due to this, even if the impurity is not sufficiently introduced to a lower portion of the second side surface 222 that is a side surface of the fins 20 in a side aligned at narrow distances, the impurity is sufficiently introduced from the upper portion to the lower portion of the first side surface 221.

Further, an impurity implanting angle (θ) is calculated by using a height (h) from the upper surface 220 of the element separation part 22 to an upper portion surface of the mask layer 14, and the distance (W3) of narrow distance taking into account of a width of the gate insulating film 24 formed on the side surfaces of the fins 20.

Next, as shown in FIG. 10K, a gate side wall 38 is formed on the side surface of the offset spacer 34 by the CVD method and the RIE method (refer to FIG. 4L), the mask layer 14 and the gate insulating film 24 are removed by the RIE method in which the gate side wall 38 is used as a mask, and the upper surface and side surface of the fins 20 are exposed. After the etching for forming the gate side wall 38, the side walls 41 formed of an insulating film remain on the second side surface 222 of the fins 20 aligned at narrow distance.

Next, as shown in FIG. 10M, an n-type impurity (for example, As) of high concentration is introduced by the ion implantation method in which the gate side wall 38 is used as a mask, the source/drain region 40 is formed, subsequently a liner film 42 is formed by the CVD method, and the FinFET 1 is obtained via well-known steps.

### (Advantages of Third Embodiment)

In accordance with the third embodiment, the following advantages can be obtained.
(1) The fins 20 are formed so as to have the wide distance (W1) and the narrow distance (W2) that are repeated, so that the impurity can be introduced into a lower portion of the fins 20 in comparison with a case that the fins are equidistantly formed.
(2) The fins 20 are formed so as to have the wide distance (W1) and the narrow distance (W2) that are repeated, consequently the impurity can be introduced into a lower portion of the fins 20, so that the parasitic resistance of the extension region 36 and the source/drain region 40 can be reduced in comparison with a case that the distance between the fins is narrow so that the impurity can not be sufficiently introduced into a lower portion of the fins.

### Fourth Embodiment

The fourth embodiment is different in that a single crystal Si is epitaxially grown on the upper surfaces and the side surfaces of the fins 20 formed by that the same distances (W3), (W4) as those of the third embodiment are repeated.

FIG. 11 is a top view schematically showing the primary portion of the FinFET of the semiconductor device according to the fourth embodiment. As shown in FIG. 11, the FinFET 1 according to the embodiment is configured to have a composition that a single crystal Si is epitaxially grown in upper surfaces and side surfaces of the fins 20, until the fins 20 adjacent to each other so as to constitute the closed loop are mutually connected. Further, the side walls 41 do not remain between the closed loops.

Hereinafter, a method of manufacturing the FinFET 1 according to the embodiment will be explained.

### (Manufacturing of Semiconductor Device)

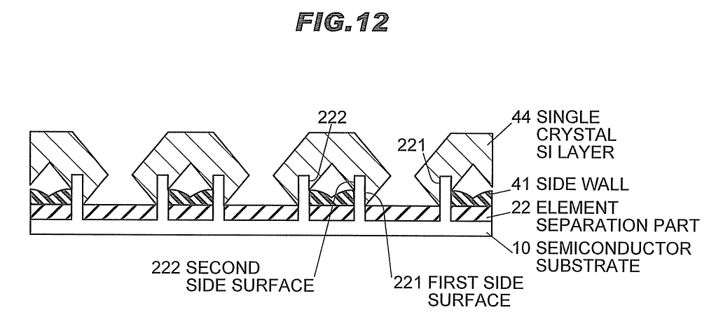

FIG. 12 is a cross-sectional view taken along the line XII-XII in FIG. 11 showing the FinFET of the semiconductor device according to the fourth embodiment.

The manufacturing steps of the semiconductor device according to the embodiment are carried out similarly to the manufacturing steps of the third embodiment shown in FIGS. 10A to 10K. However, in the step of forming the gate side wall 38, the etching being carried out for forming the gate side wall 38 further includes an overetching that is additionally carried out, and the side walls 41 that remain in the narrow distance (W3) between the fins 20 are processed so as to become side walls having a lower height than that of the side walls 41 of the other embodiments.

Next, as shown in FIG. 12, the single crystal Si is epitacially grown in the upper surfaces and the side surfaces of the fins 20 by the CVD method so as to form the contact forming regions 201 to 203. Since the second side surfaces 222 in sides of the fins 20 forming the narrow distance are exposed, the single crystal Si layers 44 epitaxially grown from the sides of the second side surfaces 222 are connected to each other earlier than the single crystal Si layers 44 epitaxially grown from the sides of the first side surfaces 221 in sides of the fins 20 forming the wide distance, so that the contact forming regions 201 to 203 can be formed.

Next, the liner film 42 is formed by the CVD method, and via well-known steps, the FinFET 1 is obtained.

### (Advantages of Fourth Embodiment)

In accordance with the fourth embodiment, when the single crystal Si layer 44 is epitaxially grown in an upper surface and a side surface of the fins 20, the single crystal Si layer 44 epitaxially grown from a side of the second side surfaces 222 is connected earlier than the single crystal Si layer 44 epitaxially grown from the first side surfaces 221 of the wide distance, so that the contacts to be connected to the contact forming regions 201 to 203 can be easily formed in an upper layer of the contact forming regions 201 to 203 that are parts connected, and a diffusing layer resistance and a contact resistance can be reduced.

### Fifth Embodiment

The fifth embodiment is different from the above-mentioned embodiments in that the fins 20 are separated from each other by cutting end portions of the closed loops.

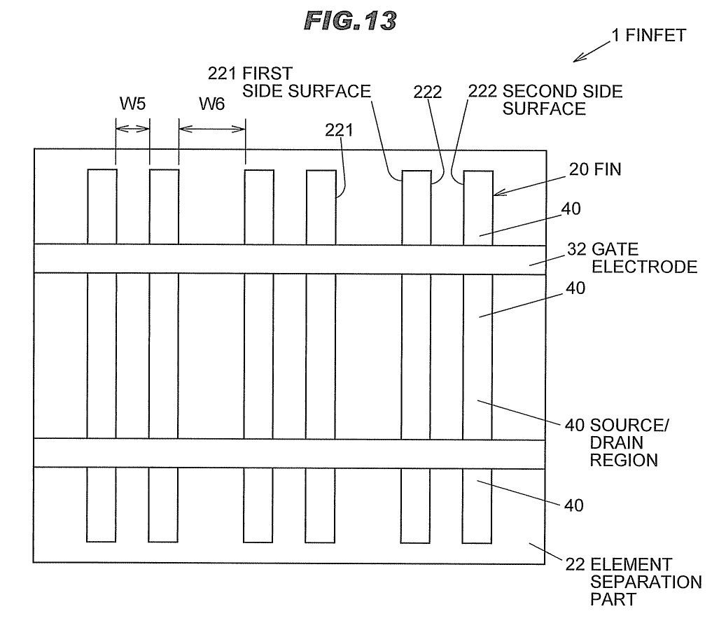

FIG. 13 is a top view schematically showing the primary portion of the FinFET of the semiconductor device according to the fifth embodiment. As shown in FIG. 13, the fins 20 are formed by that a distance (W5) and a distance (W6) having a distance wider than the distance (W5) are repeated.

Hereinafter, a method of manufacturing the FinFET 1 will be explained.

### (Manufacturing of Semiconductor Device)

The manufacturing steps of the semiconductor device according to the embodiment are carried out, for example, similarly to the manufacturing steps of the third embodiment before the liner film 42 is formed.

Next, a resist pattern having openings in which end portions where the fins 20 are connected to each other are exposed is formed on the semiconductor substrate 10 by the photolithography method or the like, the fins 20 exposed from the openings are removed by the RIE method or the like, and the resist pattern is removed. Due to this step, as shown in FIG. 13, the closed loops are cut.

Next, the liner film 42 is formed by the CVD method, and the FinFET 1 is obtained via well-known steps.

### (Advantages of Fifth Embodiment)

In accordance with the fifth embodiment, the closed loops are cut, so that integration can be easily carried out in comparison with a case that the fins form the closed loops.

### Sixth Embodiment

The sixth embodiment shows an example of static random access memory (SRAM) in which the FinFET is used.

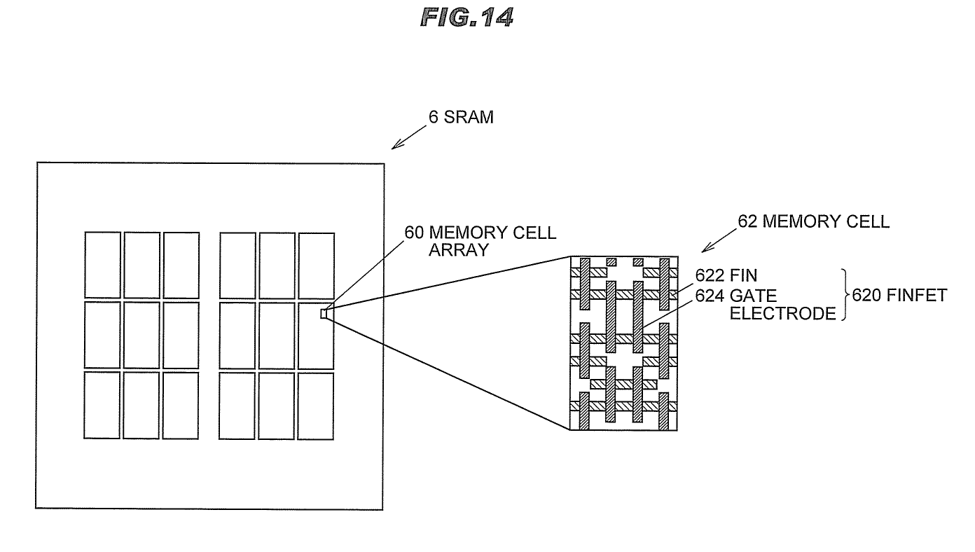

FIG. 14 is an explanatory view schematically showing a SRAM using the FinFET of the semiconductor device according to a sixth embodiment. As shown in FIG. 14, the SRAM 6 is roughly configured to include a plurality of memory cell arrays 60. The memory cell array 60 is configured to include a plurality of memory cells 62, and the memory cell 62 is configured to include a plurality of FinFETs 620.

The FinFET 620 is roughly configured to include fins 622 and gate electrodes 624. Since the fins 622 are formed so that the wide distance and the narrow distance are alternately aligned similarly to each of the above-mentioned embodiments, the impurity concentration of the fins 622 becomes approximately uniform, the parasitic resistance of the extension region and the source/drain region can be reduced, and a performance of the SRAM 6 can be enhanced.

In accordance with the sixth embodiment, the parasitic resistance of the extension region and the source/drain region can be reduced, and a performance of the SRAM 6 can be enhanced in comparison with a case that the FinFETs 620 are not used to the SRAM 6.

### (Modification)

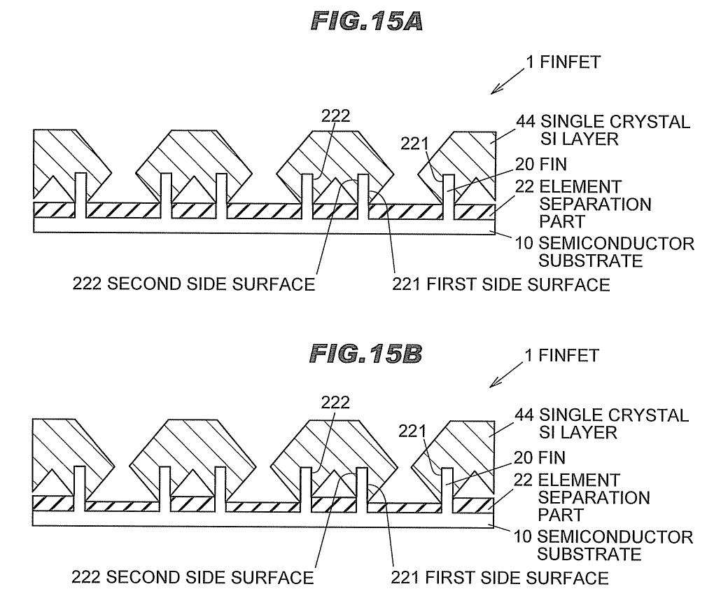

Hereinafter, a modification will be explained. FIGS. 15A and 15B are cross-sectional views schematically showing the primary portion of modifications of the FinFET of the semiconductor device according to the embodiments. The FinFET 1 shown in FIG. 15A includes single crystal Si layers 44 formed by that the single crystal Si is epitaxially grown on the first and second side surfaces 221, 222 of the fins 20 and the upper surfaces of the fins 20 by the CVD method. Since in the FinFET 1 shown in FIG. 15A, the single crystal Si is epitaxially grown from the wide regions such as the first and second side surfaces 221, 222 of the fins 20 and the upper surfaces of the fins 20, side walls are formed between the fins 20, and the diffusing layer resistance and the contact resistance of the FinFET 1 can be reduced in comparison with a case that the single crystal Si is epitaxially grown from the narrow regions of the fins 20.

In addition, the FinFET 1 shown in FIG. 15B is configured, for example, to have a composition that the element separation part 22 corresponding to the fins 20 of the wide distance has a thickness thinner than the element separation part 22 corresponding to the fins 20 of the narrow distance, and the regions for allowing the single crystal Si to epitaxilly grow are broadened in comparison with the FinFET 1 shown in FIG. 15A, so that the diffusing layer resistance and the contact resistance of the FinFET 1 can be further reduced. Further, a composition that the element separation part 22 corresponding to the fins 20 of the narrow distance has a thickness thinner can be also adopted.

While certain embodiments have been described, these embodiments have been presented by way of example only, and not intended to limit the scope of inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the above-mentioned embodiment, a double gate FinFET that does not use an upper surface of the fin as a channel has been explained as a FinFET, but a tri-gate FinFET that uses the upper surface of the fin as the channel can be also used.

What is claimed is:

1. A semiconductor device, comprising:
a substrate; and
a plurality of fins formed on the substrate,
wherein the plurality of fins is arranged so that a first distance and a second distance narrower than the first distance are repeated, and
the plurality of fins include a semiconductor region in which an impurity concentration of lower portions of side surfaces facing each other in sides forming the first distance is higher than an impurity concentration of lower portions of side surfaces facing each other in sides forming the second distance.

2. The semiconductor device according to claim 1, wherein a closed loop is formed by that end portions of two adjacent fins among the plurality of fins, the two adjacent fins having the first distance or second distance are connected with each other.

3. The semiconductor device according to claim 2, further comprising a semiconductor layer contacting upper surfaces and side surfaces of the two adjacent fins and connecting the two adjacent fins.

4. The semiconductor device according to claim 3, wherein the semiconductor layer is a single crystal Si layer.

5. The semiconductor device according to claim 1, wherein the plurality of fins contain an n-type impurity.

6. The semiconductor device according to claim 2, wherein the plurality of fins contain an n-type impurity.

7. The semiconductor device according to claim 3, the plurality of fins contain an n-type impurity.

8. The semiconductor device according to claim 4, wherein the plurality of fins contain an n-type impurity.

9. The semiconductor device according to claim 8, further comprising:
a gate electrode formed on the plurality of fins and perpendicular to an extension direction of the plurality of fins; and
a source/drain region formed in the plurality of fins.

10. A method of manufacturing a semiconductor device, comprising:
forming a mask layer on a substrate;
forming core materials aligned equidistantly on the mask layer;
forming side walls inside surfaces of the core materials;
removing the core materials leaving the side walls;
etching the mask layer by using remained side walls as the mask;
etching a part of the substrate by using etched mask layer as a mask, and forming a plurality of fins repeating a first distance and a second distance that distance is narrower than the first distance;
forming a gate electrode perpendicular to the plurality of fins;
forming a gate side wall in a side surface of the gate electrode; and
introducing an impurity into the plurality of fins by using the gate side wall as a mask, and forming a source/drain region in the plurality of fins.

11. The method of manufacturing a semiconductor device according to claim 10, wherein after the core materials are removed, both end portions of the side walls to form closed loops are cut.

12. The method of manufacturing a semiconductor device according to claim 10, wherein after the source/drain region is formed, epitaxial crystals are grown in upper surfaces and side surfaces of the plurality of adjacent fins, so that the two adjacent fins of closed loop formed by that end portions of the two adjacent fins having the first distance or the second distance are connected to each other are interconnected.

13. The method of manufacturing a semiconductor device according to claim 10, wherein the forming the core materials includes slimming the core materials.

14. The method of manufacturing a semiconductor device according to claim 12, wherein the forming the core materials includes slimming the core materials.

15. The method of manufacturing a semiconductor device according to claim 12, wherein the epitaxial crystal is a single crystal Si.

16. The method of manufacturing a semiconductor device according to claim 14, wherein the epitaxial crystal is a single crystal Si.

17. The method of manufacturing a semiconductor device according to claim 10, wherein the impurity is an n-type impurity.

18. The method of manufacturing a semiconductor device according to claim 11, wherein the impurity is an n-type impurity.

19. The method of manufacturing a semiconductor device according to claim 12, wherein the impurity is an n-type impurity.

20. The method of manufacturing a semiconductor device according to claim 16, wherein the impurity is an n-type impurity.
